(19) United States
(12) Patent Application Publication
(10) Pub. No.: US 2004/0150097 A1
(43) Pub. Date: Aug. 5, 2004

(54) OPTIMIZED CONDUCTIVE LID MOUNTING FOR INTEGRATED CIRCUIT CHIP CARRIERS

(75) Inventors: Michael A. Gaynes, Vestal, NY (US); Stefano Oggioni, Milano (IT); Giorgio Viero, Stezzano (BG) (IT)

Correspondence Address: IBM MICROELECTRONICS, INTELLECTUAL PROPERTY LAW, 1000 RIVER STREET, 972 E, ESSEX JUNCTION, VT, 05452, US

(73) Assignee: INTERNATIONAL BUSINESS MACHINES CORPORATION, Armonk, NY (US)

(21) Appl. No.: 10/707,206

(22) Filed: Nov. 26, 2003

(30) Foreign Application Priority Data
Jan. 30, 2003 (EP) 03368007.5

(51) Int. Cl. H01L 23/12; H01L 23/10

(52) U.S. Cl. 257/704; 257/707

(57) ABSTRACT

An optimized lid mounting for electronic device carriers, using standard manufacturing process steps of semiconductor packaging, optimizing heat dissipation and electromagnetic interference shielding is disclosed. According to the invention, conductive blocks or springs are soldered to ground pads of the chip carrier on their lower side. On the other side, these conductive blocks or springs are electrically connected to the lid with conductive adhesive material such as silicone based material. Furthermore, the lid is thermally connected to the semiconductor chip with electrical insulative adhesive material.

### BACKGROUND OF INVENTION

1. Field of the Invention

The present invention relates generally to semiconductor packaging and more specifically to simplified lid mounting of electronic device carriers, optimizing thermal dissipation and electromagnetic interference shielding.

2. Background of the Invention

Integrated circuits (IC) are formed on semiconductor dies, most commonly made of silicon. For handling convenience, ease of use, and reliability, the dies are often encapsulated in a protective mold material. The mold material can be ceramic, plastic, or resin. To provide an electrical interface to an IC's signal, power, and ground lines, the IC package includes an electrical connector extending from the integrated circuit to the outside of the package.

One IC package type known to those skilled in the art of IC package design is a Pin Grid Array (PGA) package. In a PGA, a plurality of pins extend from the undersurface of the package to the outside. The pins provide an electrical interface between the IC package and external circuitry. They are arranged in multiple rows and columns.

A Ball Grid Array (BGA) package is similar to a PGA package. The difference is that in a BGA package, conductive spheres replace the pins used in a PGA package. The conductive spheres are often solder balls.

Use of the conductive spheres as an electrical interface between the package and the external circuitry permits surface mounting of the BGA package. The package is placed on a Printed Circuit Board (PCB), with the conductive spheres positioned on top of the PCB's pads. For every conductive sphere there is a corresponding pad on the board. The spheres are then soldered to the pads.

One fundamental advantage of the grid array-based IC packages, such as BGA, is that they allow high density interconnects between the ICs and the printed circuit boards on which the ICs are eventually installed. The high density interconnects, i.e., high lead densities and counts, result from using all or a portion of the area of a surface of the IC for multiple rows and columns of the electrical interface. The increased area utilization in a grid array package allows chip designers to place more leads in a given package size.

High lead counts on BGA packages are needed to support high and constantly increasing IC circuit densities. High circuit densities combined with the increase of signal frequency tend to aggravate the problems of heat dissipation and susceptibility to electromagnetic interference (EMI).

To cope with heat dissipation, the lid, often being made of copper and used as a stiffener and heat spreader, is generally mounted on top of the integrated circuit using a thermally conductive material. Generally, the lid is not electrically connected to any electrical potential, leaving this copper piece “floating.” FIG. 1 illustrates how a lid is generally mounted on top of an integrated circuit, or chip, in a standard IC package 100. In this example, chip to chip carrier interconnection is performed with Controlled Collapse Chip Connection (IBM C4 technology), widely known as Flip-Chip Attach (FCA). Such technology provides high I/O density, uniform chip power distribution, high cooling capability and high reliability. Therefore, chip 110 is electrically connected to multi-layer chip carrier 120 using C4 solder balls 130. The cavity formed between chip 110 and chip carrier 120 is underfilled with dielectric material 140 such as epoxy to reinforce the chip to chip carrier electrical interconnection. Chip carrier 120 is electrically connected to a PCB (not represented for clarity) with BGA solder balls 150, as described above. Lid 160, being used for heat dissipation is thermally connected and bonded to chip 110 with thermal adhesive 170. On the external side of the package, the outside edge of the lid may be mechanically supported with a dielectric structure 180, which is also used as a stiffener. Or as in the when the lid is attached directly to the back side of the Silicon and left overhanging the chip with no stiffener placed onto the laminate.

In order to overcome EMI sensitivity, the conductive lid may be grounded by replacing the conventional electrically nonconductive adhesive for attaching the lid to the chip carrier with an electrically conductive adhesive. For example, an electrically conductive thermosetting silicone adhesive or a solder may be used as the electrically conductive adhesive.

The electrically conductive thermosetting silicone adhesive provides a mechanical buffer for reducing stress between the conductive lid and the chip carrier, caused by differences in the coefficient of thermal expansion (CTE) of the different materials joined or bonded together. However, the electrically conductive thermosetting silicone adhesive does not produce good adhesion between the chip carrier and the lid. In contrast, the solder would provide an excellent mechanical attachment between the chip carrier and the lid, but does not perform well as a stress buffer. That is, when solder is used, cracks or de-laminations may be caused at the interface between the lid and the chip carrier due to thermal stresses. Such cracks can degrade the heat removal capacity of the package and further degrade electrical performance of the chip. It is recognized that development effort for finding the right electrical and thermal conductive material providing required mechanical properties usually requires a long lead effort.

Further, it is difficult for a paste adhesive or solder to bridge the gap between the bottom surface of the lid and top surface of the chip carrier which is typically at least 0.7 mm since it would require a large pad area. This large pad area is needed to accommodate a quantity of material that has to be sufficient not only to effectively fill the gap between the laminate and the lid but, the material quantity also needs to have the right size and properties to guarantee that, when the lid is placed in contact with the dispensed material, the lid surface will be wetted by the material. Without a good wetting of the lid surface it is difficult to achieve a reliable bond.

US Patent Application Publication 2002/0113306 discloses a semiconductor package incorporating a “Faraday cage” lid design used for EMI shielding in integrated circuits. As illustrated in FIG. 2, the integrated circuit package 200 includes a substrate or chip carrier 210, a chip 220 having bond pads 230, a lid 240 attached on the upper surface of the substrate so as to cover the chip and one or more projections 250 that electrically connect the lid 240 to a plurality of ground patterns. The substrate has substrate pads formed on the upper surface, and one or more of the substrate pads extend to form the ground patterns. The chip 220 is bonded on the upper surface of the substrate 210. One or more of the bond pads 230 are ground bond pads, and the bond pads are electrically connected to the corresponding substrate pads. An electrically nonconductive adhesive 260 is used for the attachment of the lid 240 to the substrate 210, and the projections 250 are connected to the ground patterns by an electrically conductive adhesive 270. The ground projections are positioned at four corners of a cavity that is formed between the substrate 210 and the lid 240. The semiconductor package 200 further includes a thermal interface material 280, interposed between lid 240 and the chip 220, the thermal interface material 280 transmitting heat generated by the chip 220 to the lid 240.

The above described solutions present drawbacks that generally add significant time and cost in manufacturing assembly. First, as illustrated in FIG. 3, the lid with its projections must be precisely positioned to avoid any electrical short. FIG. 3 represents a partial plan view of the upper surface of the substrate 300 wherein semiconductor chip 310 is positioned. Since the size of the substrate pads 320 connected to the ground patterns, where lid projections are connected, is very small when compared to the size of the lid, such precise positioning requires adapted manufacturing tools for alignment and result in higher cycle time for placement. Circle 330 represents lid projection positions leading to electrical shorts between ground and signal tracks. Likewise, due to its physical properties and the low volume to be applied, the conductive adhesive material must be precisely positioned and dispensed. The manufacturing process may be further complicated when different adhesive materials are used simultaneously and in close proximity which could lead to direct contact between the adhesives.

### SUMMARY OF INVENTION

Thus, it is a broad aspect of the invention to remedy the shortcomings of the prior art as described above.

It is another aspect of the invention to provide a lid mounting for integrated circuit chip carriers, using standard manufacturing process steps for semiconductor packaging while optimizing heat dissipation and electromagnetic interference (EMI) shielding.

Another embodiment, incorporates an electrically floating lid but creates thermally enhanced dissipation paths between the lid and the laminate chip carrier power planes and ball grid array (BGA) footprint.

The accomplishment of these and other related aspects is achieved by a semiconductor package comprising a chip carrier including a grounded pad on a side, a semiconductor chip connected to the side of the chip carrier, a conductive lid thermally connected to the semiconductor chip and a conductive structure is electrically connected to the grounded pad and the conductive lid.

The present invention includes a method for manufacturing a semiconductor package, comprising a chip carrier having at least one grounded pad, the method comprising the steps of: applying a first electrically conductive adhesive material on the chip carrier grounded pad; providing the conductive structure coupled to the electrically conductive adhesive material; providing the semiconductor chip on the chip carrier; applying a second electrically conductive adhesive material on the conductive structure; applying electrically insulative adhesive material on the semiconductor chip; and providing a conductive lid coupled to the second electrically conductive adhesive material and the electrically insulative adhesive material.

Further advantages of the present invention will become apparent to those skilled in the art upon examination of the drawings and detailed description. It is intended that any additional advantages be incorporated herein.

### BRIEF DESCRIPTION OF DRAWINGS

Brief Description of the Drawings

FIG. 1 A prior art illustration of how lids are generally mounted on top of semiconductor chips in a standard integrated circuit package.

FIG. 2 A prior art solution of lid mounting for shielding electromagnetic interferences.

FIG. 3 A partial plan view of the upper surface of a substrate wherein a semiconductor chip is positioned, illustrating how precisely the lid must be positioned when using solution presented on FIG. 2.

FIG. 4 A partial cross section view of a semiconductor package illustrating a first embodiment of the invention.

FIG. 5 A plan view of the semiconductor package of FIG. 4.

FIG. 6 A partial cross section view of a semiconductor package illustrating a second embodiment of the invention.

FIG. 7 An example illustrating how the manufacturing process flow for implementing the present invention can be incorporated with a standard manufacturing process flow of chip packaging.

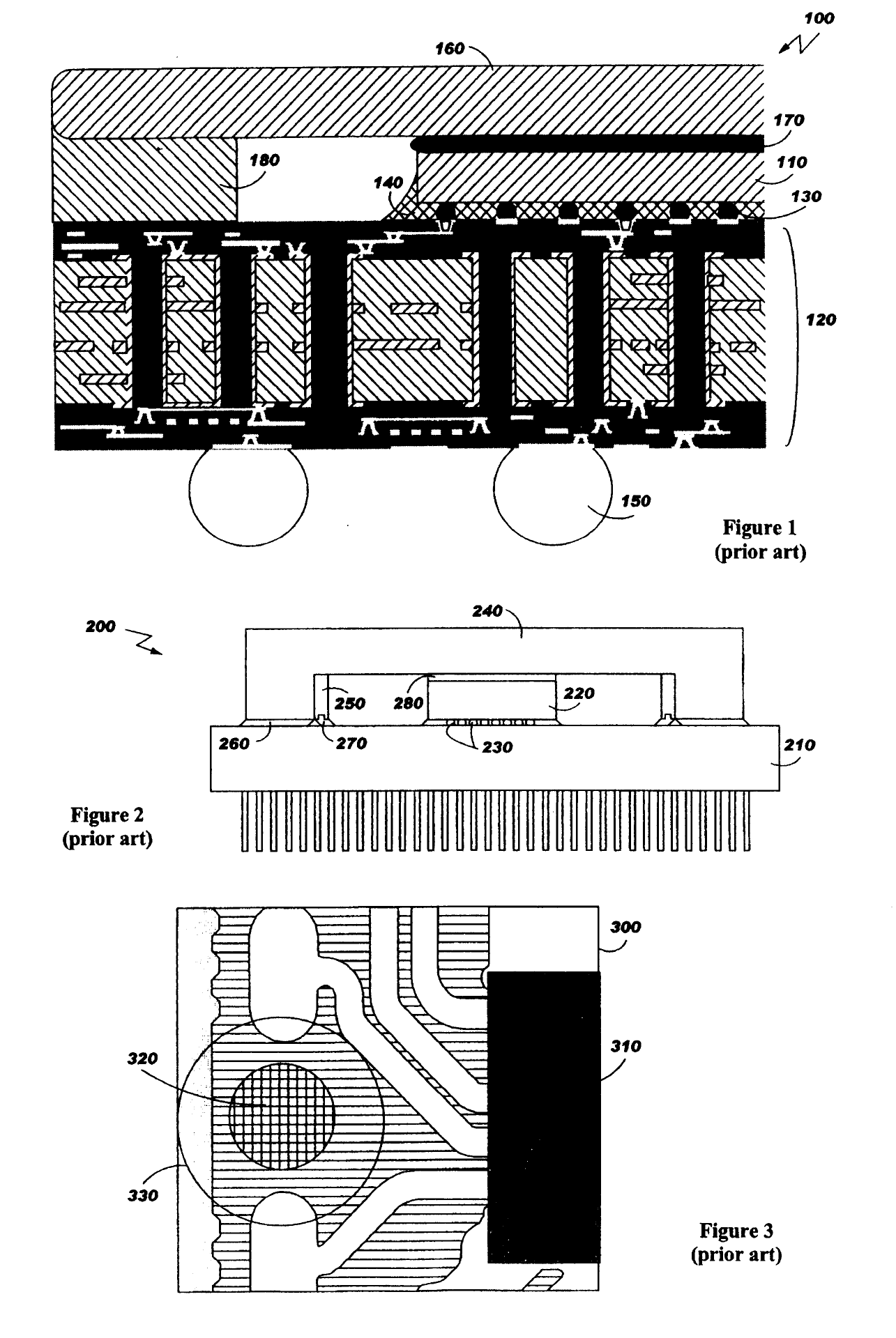

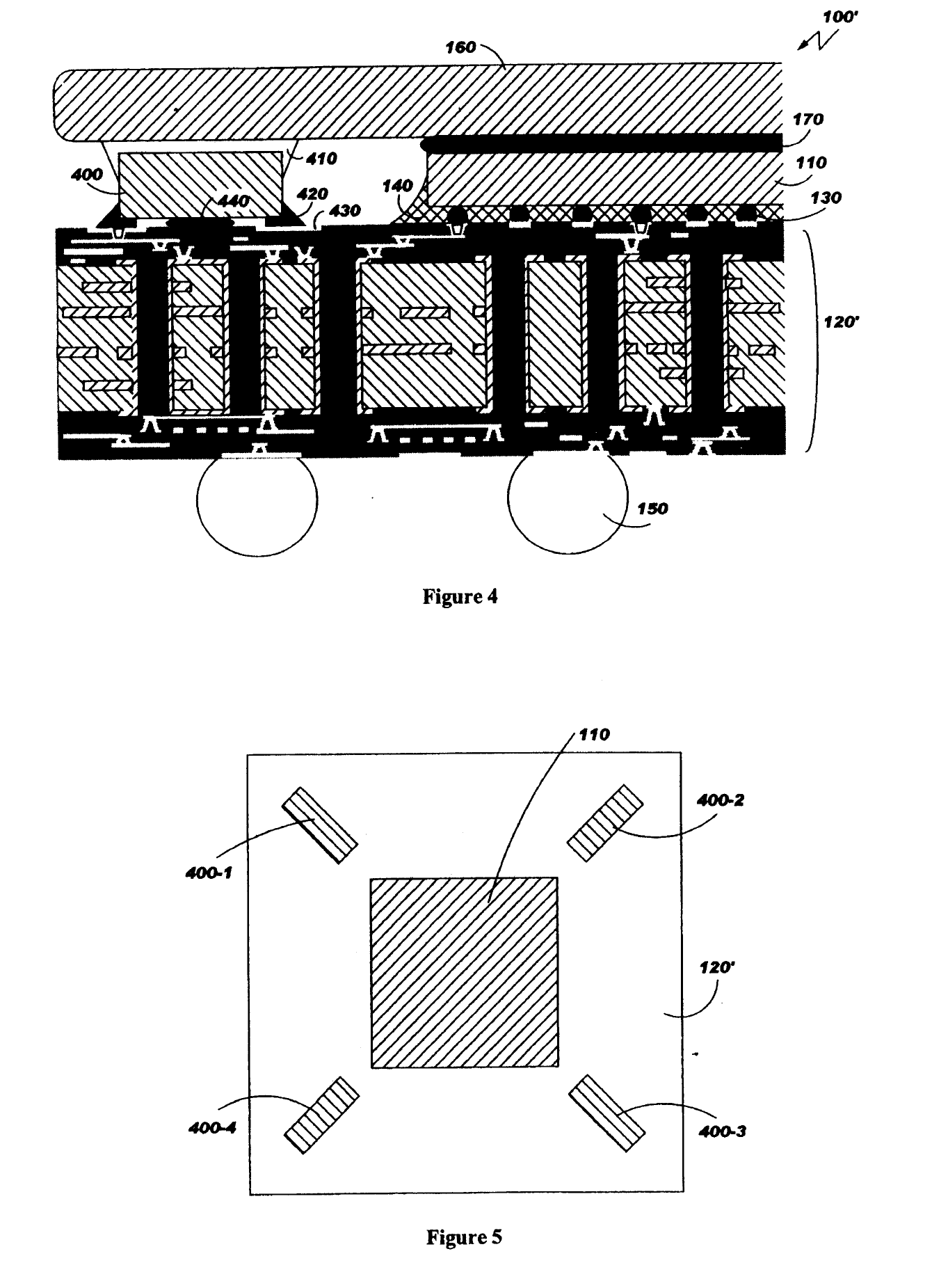

### DETAILED DESCRIPTION

According to the invention there is provided a semiconductor package having a conductive lid allowing heat dissipation and electromagnetic interference shielding, this lid being mounted with a standard manufacturing process. For purposes of illustration, the description of the invention is based upon BGA/C4 semiconductor packages however, it is understood that the invention may be implemented with other semiconductor packages.

Discrete components such as chip capacitors or chip resistors, when soldered to the chip carrier surface closely match the at least 0.7 mm gap between the bottom surface of the lid and top surface of the chip carrier. Therefore, the main principle of the invention includes using conductive modules with approximately the same dimensions as the resistor and capacitor discrete components. This allows the grounded pads of the chip carrier to bridge the conductive lid. Such conductive modules may be soldered on grounded pads and electrically connected to the conductive lid with an electrically conductive adhesive.

FIG. 4 illustrates a first embodiment of the semiconductor package according to the invention. The semiconductor package 100′ of the invention comprises a semiconductor chip 110 positioned on a chip carrier 120′ and electrically connected to signal and ground tracks of external conductive layer through C4 solder balls 130. The cavity formed between chip 110 and chip carrier 120′ may be underfilled with dielectric material such as epoxy to reinforce the chip to chip carrier electrical connection. Chip carrier 120′ is electrically connected to a PCB (not represented for purposes of clarity) with conductive BGA solder balls 150. The conductive lid 160 is used for heat dissipation and is thermally connected and mechanically bonded to chip 110 with thermal adhesive 170.

Referring to FIG. 4, the conductive lid 160 is electrically connected to ground pad 430 through a conductive structure 400 that could be made, for example, of copper. On its upper side, conductive structure 400 is electrically connected to lid 160 with conductive adhesive material 410. A silicone based material or similarly compliant adhesive such as low modulus epoxies, polyurethanes or acrylics may be used for this purpose. On its lower side, conductive structure 400 is soldered 420, or electrically connected with electrically conductive adhesive material, to a pad 430, designed in the chip carrier 120′ and connected to a ground track. Conductive structure 400 may also be bonded to chip carrier 120′ with non conductive adhesive material 440 to avoid any displacement during manufacturing.

The conductive structure 400 shown in FIG. 4 can be nickel plated on one or two sides for improved compatibility of the adhesion properties of silicone based material. The conductive structure 400 is preferably a cubic or block shaped module with geometry similar to surface mount technology discrete component. Similarly, the conductive lid that may be made of copper may also be nickel plated. Further, one skilled in the art will know that other surface treatment choices that provide low and stable contact resistance could be used for either the block or the lid. These choices include passivated copper, tin, tin-lead, or noble metals such as gold, silver, palladium, silver-palladium or palladium-nickel alloys.

As mentioned above the conductive block 400 should conform to the physical dimensions applicable to standard surface mount technology (SMT) discrete components, which are commonly placed on board of chip carriers. In this way, standard pick and place tools may be used in the manufacturing process. The present invention is further directed to a conductive lid 160 that is electrically connected to ground tracks of chip carrier 120′ through four conductive blocks 400-1 to 400-4 as illustrated in FIG. 5, representing a partial plan view of the semiconductor package 100′. Furthermore, even though conductive block 400 is soldered on two different pads as shown in FIG. 4, only one is required to electrically connect a ground track of chip carrier 120′ to conductive lid 160.

The copper conductive block 400 attached with solder joints along the laminate chip carrier side, and the electrically and thermally conductive adhesive on the lid side represent an ideal thermal dissipation path from the conductive lid heat spreader (lid) to the ground plane network within the laminate chip carrier. This configuration enhances the thermal dissipation properties of the electronic package. The same thermal performance benefit is achieved using a non electrically conductive resin but with specific or optimized thermal conductivity characteristics between the copper block and the lid.

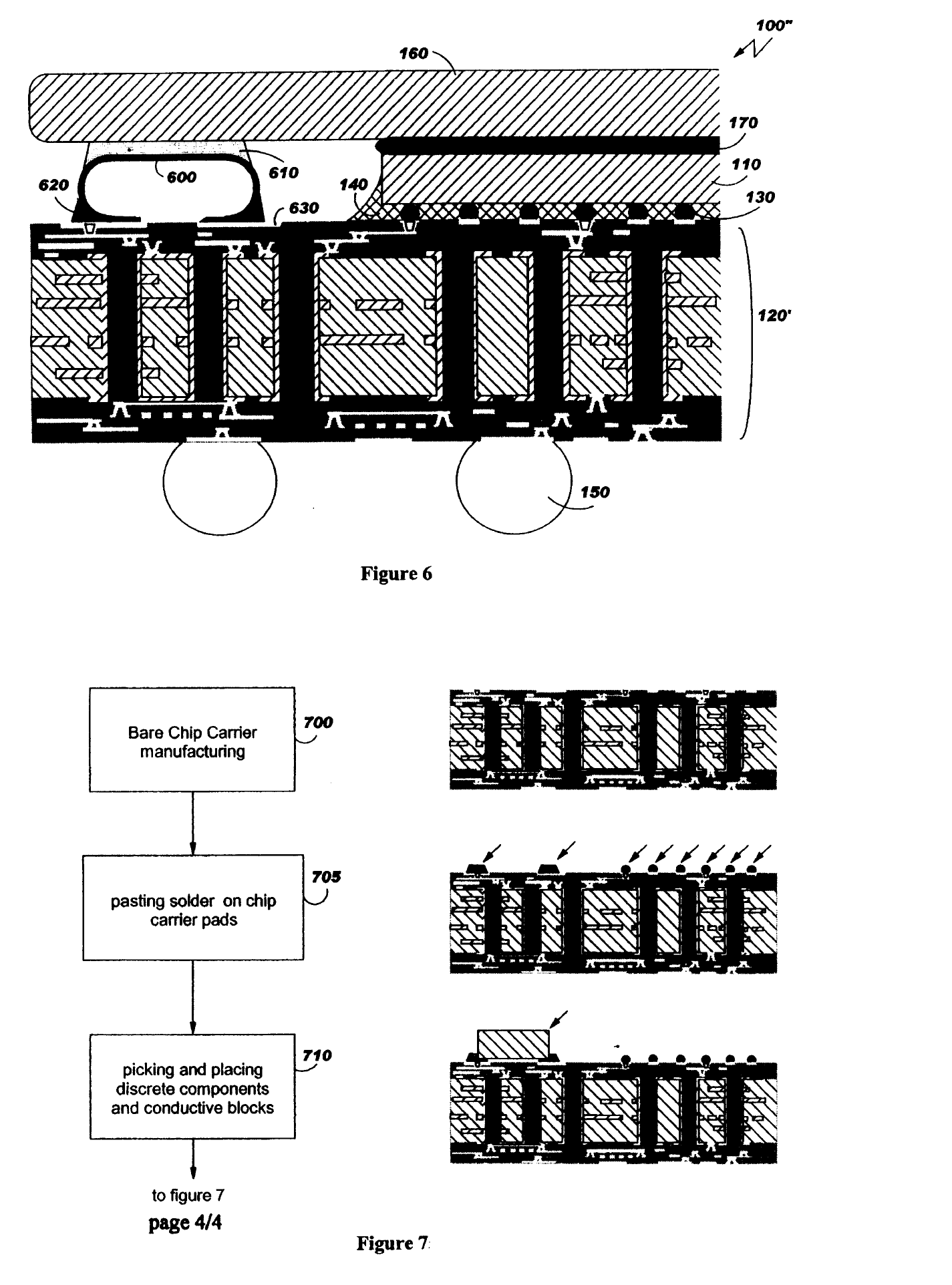

FIG. 6 illustrates a second embodiment of the semiconductor package according to the invention. Semiconductor package 100″ still comprises a semiconductor chip 110 positioned on a chip carrier 120′ and electrically connected to signal and ground tracks of external conductive layer through C4 solder balls 130. The cavity formed between chip 110 and chip carrier 120′ may be underfilled with dielectric material such as epoxy to reinforce the chip to chip carrier electrical interconnection. Likewise, chip carrier 120′ is electrically connected to a PCB (not represented for purposes of clarity) with conductive BGA solder balls 150. Conductive lid 160, is thermally connected and mechanically bonded to chip 110 with thermal adhesive 170 to provide a path for heat dissipation.

According to the second embodiment of the invention, the conductive block 400 of FIG. 4 is replaced by the spring shown in FIG. 6, which may be composed of a copper beryllium (CuBe) alloy. Referring to FIG. 6, the spring connecting conductive lid 160 and the chip carrier 120′ effectively compensates for discrepancies in the coefficient of thermal expansion (CTE) between large components (lids and carriers). For example, when a copper lid is mounted on a ceramic carrier or attached to organic laminates. Thermal dissipation properties are further enhanced if CuBe springs are placed along the longer diagonal of the semiconductor package as illustrated in FIG. 5.

As noted above, the invention is based upon the standard process flow currently available in chip manufacturing and the available process capability of the equipment set. For example, referring to FIG. 4, the conductive structure 400 can be obtained from a metal reel and embedded into embossed tapes and reeled for pick and place utilization.

According to the present invention, approximately 90% of the gap between the carrier and the conductive lid is covered by the conductive block 400 or spring 600, leaving only a thin gap to be filled with the electrically conductive adhesive 610. The conductive adhesive material 410 or 610 can be deposited on the conductive block 400 or spring 600 by the same tool and at the same time as the other silicone based material 170 is distributed between the lid and the back side of the chip 110. The process for attaching the conductive lid remains the same. When compared to silicone or ceramic materials, strain and stress build up are less of a concern due to the unique physical properties of the conductive structure 400. CTE mismatch between lid and chip carrier or lid and semiconductor is not an issue because of the compliant property of the silicone adhesive. Soldering of the conductive structure is fully compatible with the current manufacturing process flow and the resulting solder joint is mechanically stronger compared, for example, with adhesive posts.

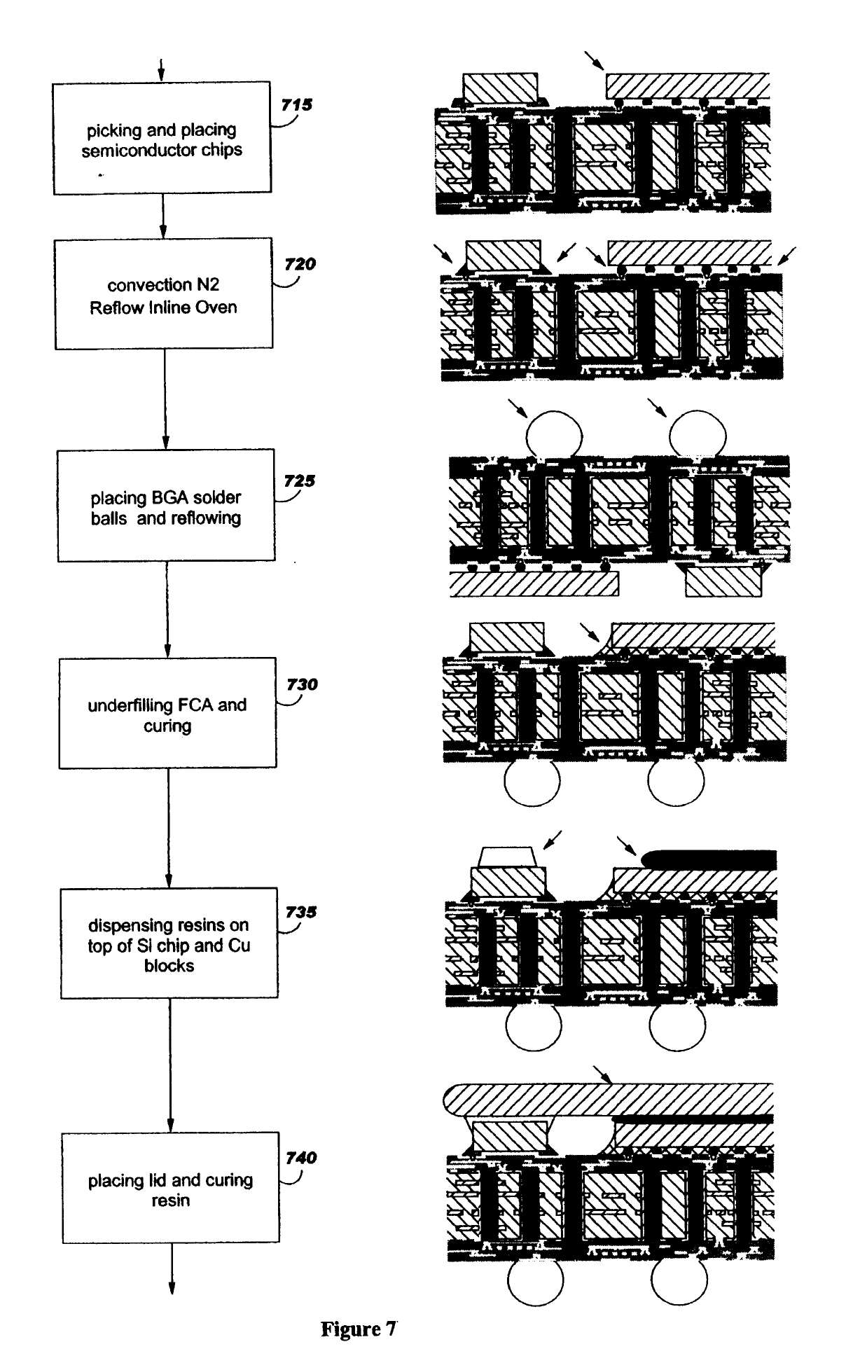

FIG. 7 illustrates the main steps of the manufacturing process flow used for semiconductor packaging, allowing the implementation of the invention. The bare chip carrier is manufactured according to standard design rules and processes (step 700). Implementing the invention requires designing pads connected to ground tracks at the surface layer of the chip carrier on the lid side. This pad design is a standard implementation for chip electrical connections. When depositing solder alloy on the C4 receiving pad of the laminate chip carrier to connect the chip, solder is also deposited on chip carrier pads, where discrete components and conductive blocks linking chip carrier to lid must be placed (step 705). After solder has been applied, discrete components and conductive structures linking chip carrier to lid are automatically picked and placed (step 710). As mentioned above, discrete components and conductive structures, having approximately the same size, allow the same pick and place tool to be used for both operations. A dot of glue may be disposed between the chip carrier and the discrete components and conductive structures before they are placed to avoid misalignment. Similarly, semiconductor chips are picked and placed (step 715). Following these pick and place steps, a reflowing operation is performed to solder discrete components, conductive structures linking chip carrier to lid and chips (step 720). Then, BGA solder balls are put in place, a reflowing operation is performed (step 725) and, after electrical test, the space comprised between semiconductor chip and chip carrier is underfilled with a dielectric material that is cured (step 730). Then, adhesive materials such as resins are disposed on top of the semiconductor chips and the conductive structures linking chip carrier to lid (step 735). The adhesive material disposed on top of the semiconductor chips is insulative while the one disposed on top of the conductive structures linking the chip carrier to the lid is conductive. When the adhesive material is dispensed, the lid 160 is placed and the adhesive material 610, 170 is cured (step 740).

While the process has been described to implement the invention according to the first embodiment wherein conductive blocks are used to link chip carrier to lid, the process to implement the second embodiment wherein conductive springs are used to link chip carrier 120″ to conductive lid 160 is similar.

As shown in FIG. 7, the invention is based upon standard process flow for semiconductor chip package manufacturing, thereby allowing efficient heat dissipation and electromagnetic interference (EMI) shielding without increasing manufacturing costs.

Surface mount technology (SMT) discrete components may be used to replace conductive blocks or springs. This approach avoids having to adapt conductive blocks with non-standard features regarding size, coefficient of thermal expansion and adhesivity. In such a case, the SMT discrete components are used only to connect chip carrier ground to the lid and are not acting as a resistor or capacitor. It could also be possible to use other components integrating several functions. For example, one being dedicated to electrically connect chip carrier ground to the lid and the remaining two to the original discrete component destination of electrical contact for a passive electrical component.

While the invention has been described in detail, the foregoing description is in all aspects illustrative and not restrictive. It is understood that numerous other modifications and variations can be devised without departing from the scope of the invention.

1. A semiconductor package comprising:
a chip carrier including a grounded pad on a first side of said chip carrier;
a semiconductor chip coupled to said first side of said chip carrier;
a conductive lid thermally coupled to said semiconductor chip; and
a conductive structure electrically coupled to said grounded pad and to said conductive lid.

2. The semiconductor package according to claim 1 wherein a solder connects said conductive structure and said grounded pad.

3. The semiconductor package according to claim 1 wherein said conductive structure is electrically coupled to said grounded pad with an electrically conductive adhesive material.

4. The semiconductor package according to claim 1 wherein said conductive structure is electrically coupled to said conductive lid with an electrically conductive adhesive material.

5. The semiconductor package according to claim 1 wherein said conductive structure is coupled to said chip carrier using an electrically insulative adhesive material.

6. The semiconductor package according to claim 1 wherein said conductive structure is coupled to said chip carrier using a thermally conductive adhesive material.

7. The semiconductor package according to claim 1 wherein said conductive structure comprises a spring.

8. The semiconductor package according to claim 1 wherein said conductive structure comprises a block.

9. The semiconductor package according to claim 1 wherein said block comprises a surface mount technology (SMT) discrete component.

10. The semiconductor package according to claim 1 wherein
a solder couples said conductive structure to said grounded pad;
an electrically conductive adhesive material couples said conductive structure to said conductive lid; and
an electrically insulative adhesive material couples said conductive structure to the chip carrier.

11. The semiconductor package according to claim 10 wherein said conductive structure comprises a conductive spring.

12. The semiconductor package according to claim 10 wherein said conductive structure comprises a block.

13. The semiconductor package according to claim 10 wherein said conductive structure comprises a surface mount technology (SMT) discrete component.

14. A method for manufacturing a semiconductor package, the semiconductor package including a chip carrier having a grounded pad, said method comprising the steps of:
applying a first electrically conductive adhesive material on said grounded pad;
providing a conductive structure coupled to said first electrically conductive adhesive material;
providing a semiconductor chip on said chip carrier;
applying a second electrically conductive adhesive material on said conductive structure;
applying electrically insulative adhesive material on said semiconductor chip; and
providing a conductive lid coupled to said second electrically conductive adhesive material and said electrically insulative adhesive material.

15. The method according to claim 14 wherein said first electrically conductive adhesive material comprises solder.

16. The method according to claim 14 wherein said conductive structure comprises a conductive spring.

17. The method according to claim 14 wherein said conductive structure comprises a surface mount technology (SMT) discrete component.

18. The method according to claim 14 wherein said conductive structure comprises a conductive block.

19. The method according to claim 14 wherein the step of providing said conductive structure coupled to said first electrically conductive adhesive material comprises picking said conductive structure from a first location and placing said conductive structure on said first electrically conductive adhesive material.

20. The method according to claim 14 wherein the step of providing said semiconductor chip on said chip carrier comprises picking said semiconductor chip from a second location and placing said semiconductor chip on said chip carrier.
